(19) United States
(12) Patent Application Publication
(10) Pub. No.: US 2008/0001213 A1
(43) Pub. Date: Jan. 3, 2008

(54) STRUCTURES AND METHODS FOR MANUFACTURING HIGH DENSITY NARROW WIDTH MOSFETS

(75) Inventors: Huilong Zhu, Poughkeepsie, NY (US); Byeong Y. Kim, Lagrangeville, NY (US); Effendi Leobandung, Wappingers Falls, NY (US)

Correspondence Address: WHITHAM, CURTIS & CHRISTOFFERSON, P.C., 11491 SUNSET HILLS ROAD, SUITE 340, RESTON, VA, 20190, US

(73) Assignee: INTERNATIONAL BUSINESS MACHINES CORPORATION, Armonk, NY (US)

(21) Appl. No.: 11/427,405

(22) Filed: Jun. 29, 2006

(51) Int. Cl. H01L 29/76

(52) U.S. Cl. 257/327

(57) ABSTRACT

Reverse narrow width effects are provided consistent with reduced spacing between field effect transistors by an impurity or dopant implantation perpendicular to a semiconductor substrate through gaps formed by selective removal of a layer of material deposited to a selected thickness rather than implantation at an angle in accordance with a patterned resist resulting in superior accuracy, controllability and repeatability of the location of the implanted region and avoidance of implantation at undesired locations. A multi-layer structure having at least three component materials which can be removed selectively to each other is preferred for forming the gaps for confining the implantation preferably performed through a layer of one of the component materials which also functions as an etch stop.

### BACKGROUND OF THE INVENTION

1. Field of the Invention

The present invention generally relates to transistors suitable for use in integrated circuits and, more particularly, to metal-oxide-semiconductor field effect transistors (MOSFETs) formed at high density and narrow width and exhibiting a reverse narrow width effect (NWE) which are particularly suitable for narrow width MOSFETs such as SRAMs.

2. Description of the Prior Art

The potential for improvements in performance and functionality as well as manufacturing economy has historically led to higher degrees of miniaturization of devices formed together as integrated circuits. By the same token, increasingly sophisticated designs for transistors and other devices have been developed to accommodate effects which become significant as devices are scaled to smaller sizes. Unfortunately, the manufacturing processes which may be needed to manufacture such sophisticated designs are not necessarily compatible with increased integration density due to material properties and constraints.

For example, when the channel width of a field effect transistor is reduced to very narrow dimensions, as is particularly desirable for SRAMs and the like, the threshold voltage, Vₜ, is significantly reduced due to effects altering the electrical field in the corners of the channel and is referred to as a narrow width effect. To neutralize this narrow width effect (NWE), an impurity/dopant implant is performed at the corners of the channel or in a sidewall formed thereon to increase the threshold voltage which is referred to as a reverse NWE. Such implants are usually performed at a tilt angle greater than 15° using a thick photoresist or nitride to avoid implantation at undesired locations which, in turn, requires large spacing between devices for the photoresist or nitride and to accommodate etching to provide gaps through which implantation may be performed into the sides of the transistor channels. Moreover, it is difficult to accurately control dimensions of nitride where the dimensions thereof are developed by etching and such dimensional inaccuracy alters the distribution of impurities/dopants in the FET channel and thus develops reverse NWE in varying degrees which has the very undesirable effect of varying the threshold voltage of the transistors.

### SUMMARY OF THE INVENTION

It is therefore an object of the present invention to provide a technique and structure for producing narrow channel MOSFETs exhibiting reverse NWE at much higher density and reduced pitch than has been achieved heretofore.

It is another object of the invention to provide a technique and structure for producing implants to engender reverse NWE in narrow width FETs with much higher accuracy of impurity/dopant distribution to achieve much more uniform and repeatable tailoring of threshold voltage.

In order to accomplish these and other objects of the invention, a field effect transistor and an integrated circuit including a field effect transistor are provided wherein the field effect transistor comprises a channel having a width sufficiently narrow to exhibit narrow width effects, an implanted region at corners of the channel wherein impurities or dopant materials are confined to a width not exceeding 50 nm.

In accordance with another aspect of the invention, a method of manufacture of a field effect transistor is provided including steps of developing raised STI structures on a substrate between regions of semiconductor material on a substrate, depositing a layer of material selectively etchable to the STI structure over the STI structure and the regions of semiconductor materials, developing a deposit of material over the layer of material between the STI structures which is selectively etchable to the layer of material, removing exposed portions of the layer of material to form gaps at edges of the regions of semiconductor material, masking selected regions of the semiconductor material, implanting impurities or dopant materials through the gaps into the regions of semiconductor materials, and completing the field effect transistor.

### BRIEF DESCRIPTION OF THE DRAWINGS

The foregoing and other objects, aspects and advantages will be better understood from the following detailed description of a preferred embodiment of the invention with reference to the drawings, in which:

FIG. 1A illustrates a conventional technique for performing implants to engender reverse NWE,

FIG. 1B graphically illustrates an impurity profile, produced by simulation, at an undesired location in a pull-up transistor PU of FIG. 1A resulting from a desired implantation operation in forming the pull-down transistor PD in FIG. 1A,

FIG. 2 illustrates, in cross-section, an initial stage in the production of a narrow channel transistor in accordance with the invention,

FIGS. 3, 4, 5, 6, 7, 8, 9, 10, 11, 12, 13 and 14 illustrate, in cross-section, intermediate stages in production of a narrow channel transistor in accordance with the invention, and

FIG. 15 illustrates, in cross-section, the structure in accordance with the invention, including the impurity/dopant locations achieved thereby suitable for completion of narrow channel transistors using known techniques.

### DETAILED DESCRIPTION OF A PREFERRED EMBODIMENT OF THE INVENTION

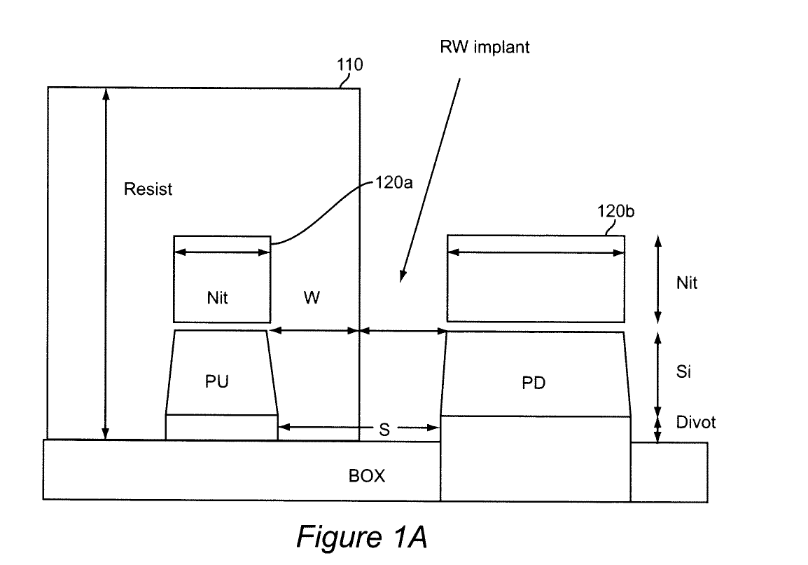

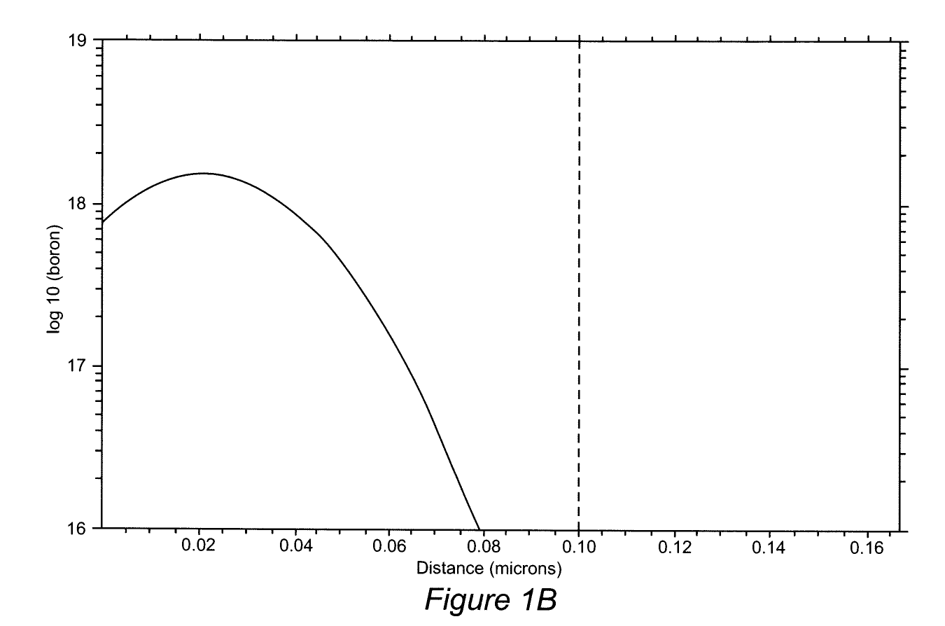

Referring now to the drawings, and more particularly to FIGS. 1A and 1B, there is schematically shown, in cross-section, an intermediate stage of production of a pair of narrow channel transistors which will be useful in conveying an understanding of the problems addressed by the invention. It is to be understood that FIG. 1A is a highly schematic representation of a portion of a chip for purposes of illustrating critical geometry of a proposed technique for engendering a reverse narrow with effect (NWE) with an angled implant as related to a device formed using particular design ground rules which would necessarily be violated by the required angled implant and/or masking. FIG. 1B is a graphical depiction of a simulation illustrating an impurity dopant profile in an undesired location which would be generated using the geometry of FIG. 1A. Accordingly, no portion of FIG. 1A or 1B is admitted to be prior art in regard to the present invention (for the simple reason that it is essentially a hypothetical impractical and unacceptable structure and thus is not necessarily known or used by others) even though the present invention is not represented therein.

FIG. 1A schematically depicts conduction channels of a pair of complementary transistors (which may be connected in series as in CMOS devices) including a PMOS pull-up transistor, PU, and an NMOS pull-down transistor PD. Gate electrodes are omitted from FIG. 1A in the interest of clarity and the source and drain structures are in front and back of the plane of the page. The particulars of the gate, source and drain structures are, in any case, irrelevant to the principles and/or practice of the invention. The NMOS transistor is depicted as having a wider channel (by an exemplary factor of two) than the PMOS transistor to derive more nearly symmetric electrical characteristics and operation of the transistor pair for SRAM applications. However, the relative width of the transistors is also unimportant to the practice of the invention in accordance with its basic principles but it is assumed that the widths of the respective channels are is exemplary of channel widths at which NWE would be observed. These transistor channels are preferably formed, for example on a buried oxide (BOX) layer of a semiconductor on insulator (SOI) wafer and the BOX layer is preferably recessed to provide reduced source and drain resistance although this preferred feature is also of no importance in regard to the practice of the invention.

As alluded to above, engendering of the reverse NWE requires the placement of impurities or dopants in the upper corners of the channel(s) of the respective transistors and doing so has generally been achieved using masking such as with resist 110 and nitride caps 120a and 120b. However, the nitride caps do not cover the sides of the transistor channels and implantation into the sidewalls of the channels must be prevented by photoresist (PR) masking 110.

Under the ground rules of interest, however, the maximum separation of transistors, S, is as small as possible (e.g. minimum feature size), implying a maximum nominal PR thickness of S/2. If impurities are implanted into channel PD at an angle of about 20° to the perpendicular to the substrate, as is appropriate to the desired impurity concentration profile therein, even a PR thickness of 79 nm allows a significant implantation to occur in an undesired location in channel PU as depicted in FIG. 1B. It should be understood that this effect will occur to some degree in transistor channel PD when similarly masked for an implant of phosphorus or arsenic, appropriate to engendering reverse NWE in the PMOS transistor PU but that an implant of boron, appropriate to producing reverse NWE in an NMOS device PD, yields a more pronounced undesired implantation in the PMOS device PU and thus is described here as exemplary of the effect in either transistor. The boron concentration profile illustrated in FIG. 1B is for an exemplary PR thickness of 79 nm and thus clearly demonstrates that a nominal minimum PR thickness of 40 nm (or about half the thickness assumed for the simulation depicted) specified by exemplary design ground rules of 100 nm (or less in foreseeable ground rules) is clearly insufficient to prevent undesired implantation regard to boron, and probably for the phosphorus or arsenic implant to develop reverse NWE in the PMOS transistor in a similar operation.

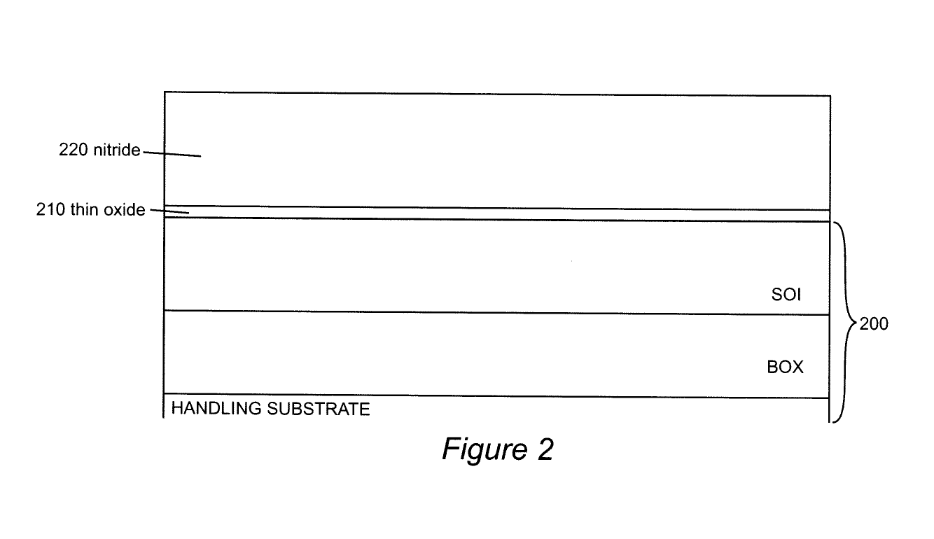

Referring now to FIG. 2, an initial stage in the formation of a structure in accordance with the invention is illustrated in cross-section. It is assumed for purposes of this discussion of the invention that the transistors are formed on a semiconductor-on-insulator (SOI) wafer, as is preferred due to the quality of semiconductor material available on such wafers. However, the invention, in accordance with its basic principles, can be equally applied to any other semiconductor substrate, as will be recognized by those skilled in the art. As is well-known, an SOI wafer 200 comprises a handling substrate, a buried oxide (BOX) insulator layer and a layer of semiconductor material (also referred to as SOI) such as silicon over the BOX. If another type of wafer is employed in the practice of the invention, it may be necessary to form either or both of layers corresponding to the insulator and semiconductor layers on such a substrate.

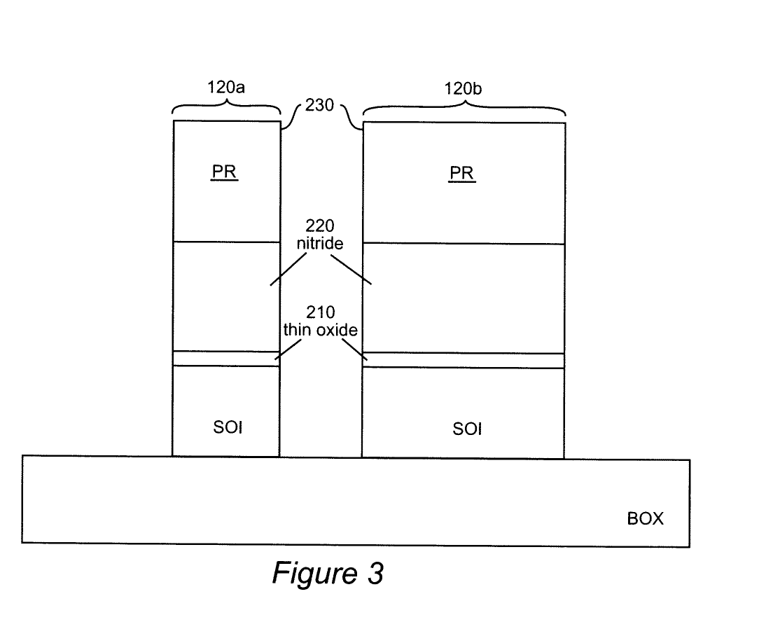

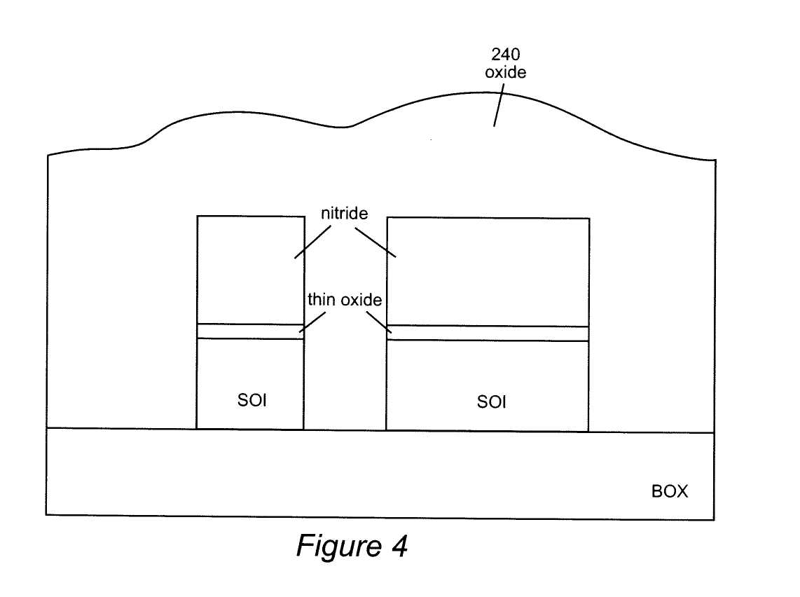

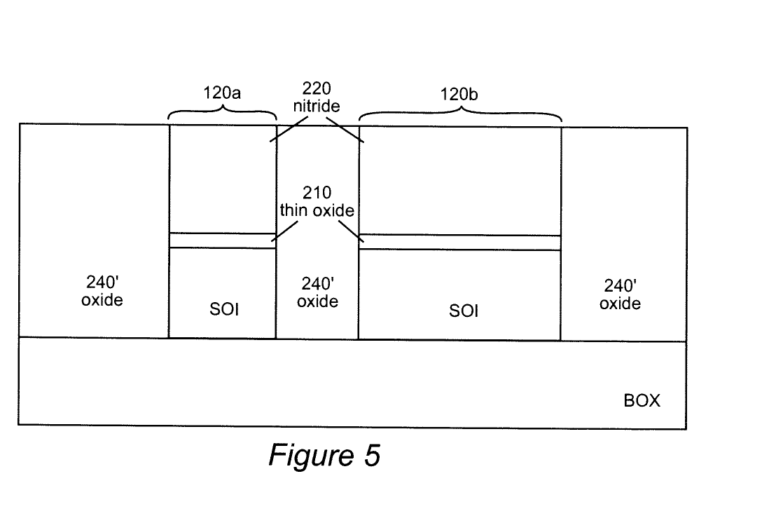

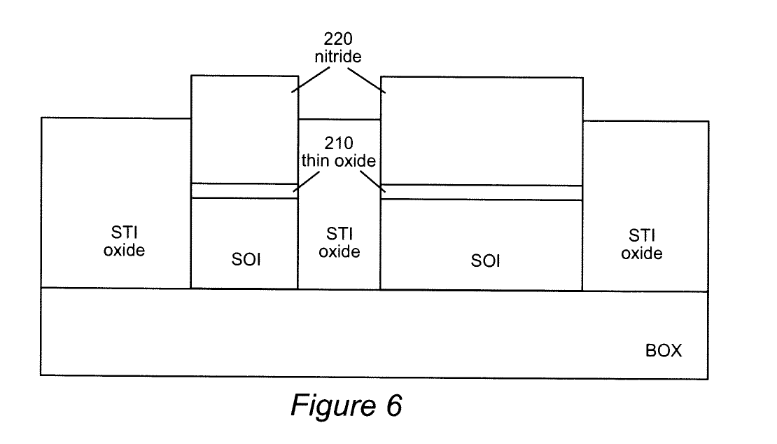

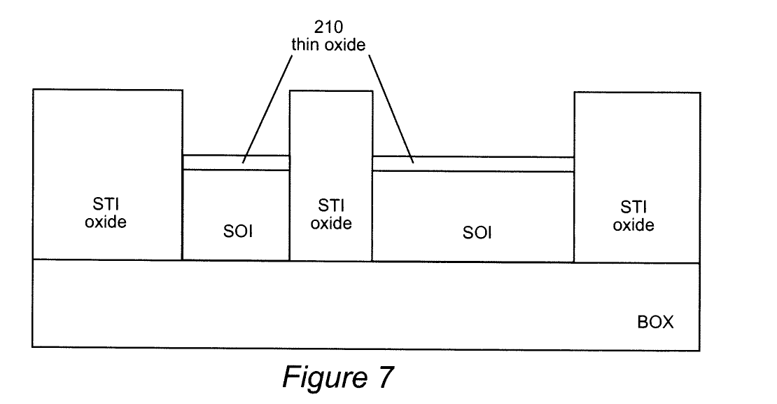

As shown in FIG. 2 and assuming that a SOI wafer is used, the process begins with deposition or growth of a thin oxide layer 210 followed by deposition of a nitride layer 220 to a non-critical thickness of about 50-100 nm. Then, as shown in FIG. 3, a photoresist PR 230 is applied and patterned to define the transistor channels 120a, 120b and the nitride 220, thin oxide 210 and SOI are etched, preferably by reactive ion etching (RIE) to the BOX. The photoresist is then removed and a thick blanket layer of oxide 240 is deposited, as shown in FIG. 4. This structure is planarized, preferably by chemical-mechanical polishing (CMP) to the nitride 220, leaving oxide deposits 240′ between the regions which will become the transistor channels 120a, 120b, as shown in FIG. 5. Deposits 240′ become shallow trench isolation (STI) structures which are etched back as shown in FIG. 6 for a distance below the nitride 220 which is non-critical as long as the surface of the STI structures is above the thin oxide 210. Then, the nitride 220 can be removed by etching using a process which is selective to oxide (e.g. of the STI structures and the thin oxide 210, as shown in FIG. 7.

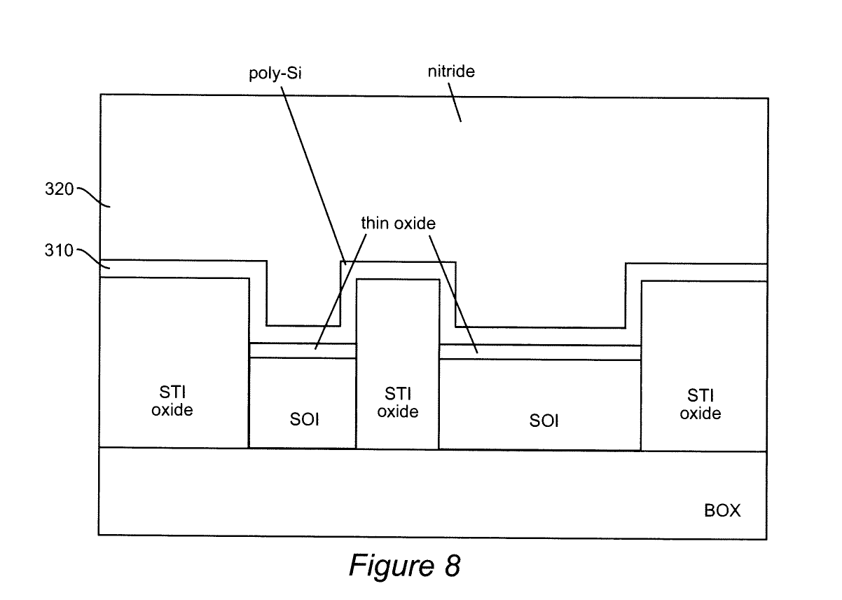

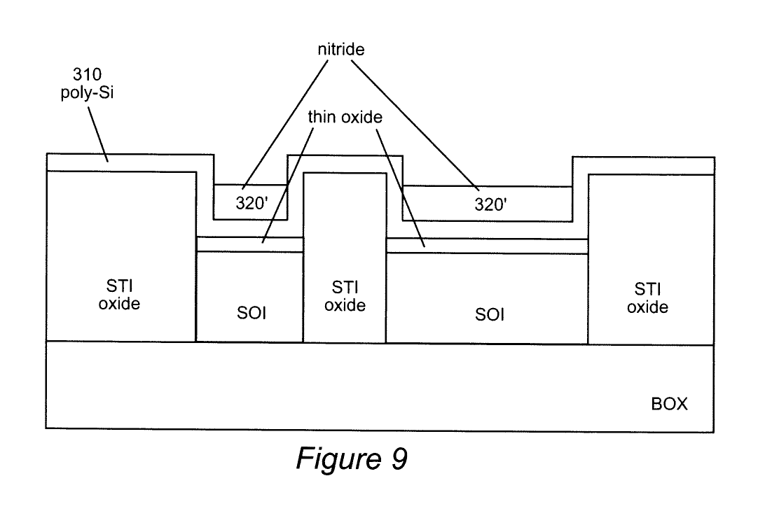

Referring now to FIG. 8, processes which are particularly important to the practice of the invention will now be discussed. First, a thin layer of polysilicon 310 or other material of a thickness which is non-critical but which should be determined based on the impurity/dopant distribution geometry desired at the corners of the respective transistor channels, generally about 10-30 nm, is deposited. As alluded to above, the deposition thickness may be much more reliably controlled and the thickness developed much more uniformly than is achievable by an etching or mask patterning process. This deposition is followed by deposition of a relatively thick nitride blanket layer 320, preferably of 200-500 nm thickness. The nitride is then selectively etched back to expose the top portion of the thin polysilicon layer 310 while leaving separated nitride deposits 320′. The height of the STI oxide, alluded to above, establishes the nitride overetch margin for this process, as particularly shown in FIG. 9. It should be noted that it is only necessary for practice of the invention to provide a structure over the layer 310 in which two layers (e.g. poly-Si 310′ and nitride 320′) are selectively etchable with respect to each other and thin oxide layer 210 so that exposed portions of layer 310 can be removed leaving other materials substantially intact and forming an etch stop and a multi-layered structure when removal of exposed portions of layer 310 is performed. Therefore, other materials can be used in the steps and structure described above although oxide, nitride and polysilicon are much preferred for deposits 210 and 320′ and layer 310, respectively.

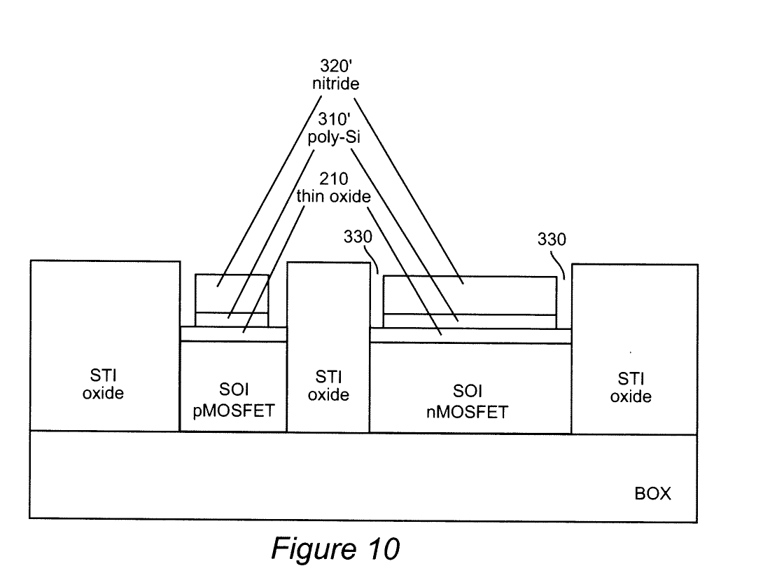

Then, as shown in FIG. 10, the thin polysilicon layer is selectively etched, where exposed, to thin oxide 210 using the nitride deposits 320′ as a hard mask. This etching process, by selectively removing polysilicon in a substantially self-limiting process, forms gaps 330 through which implantation will later be performed.

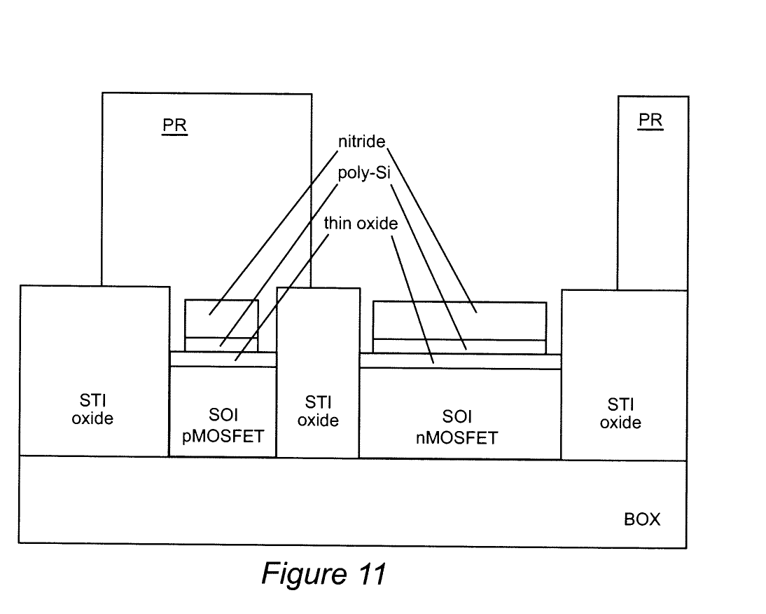

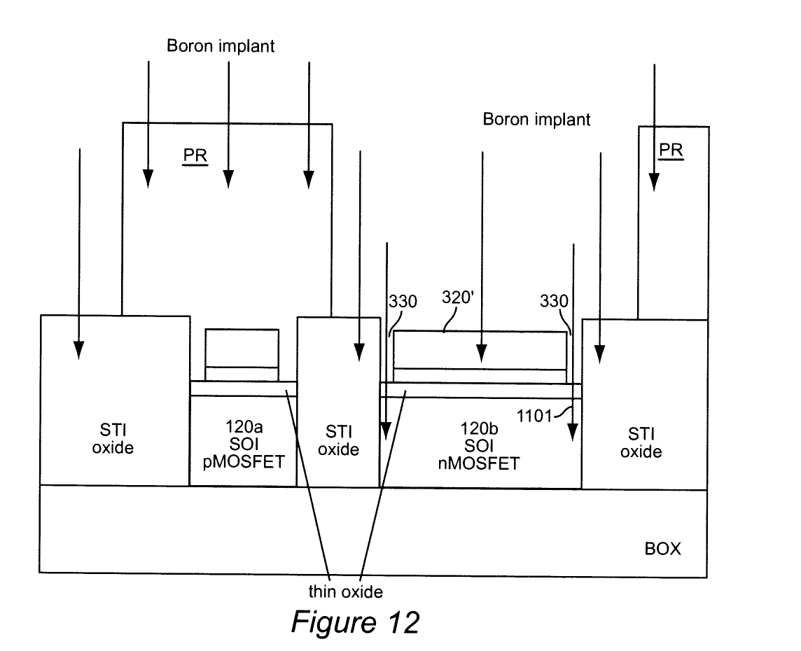

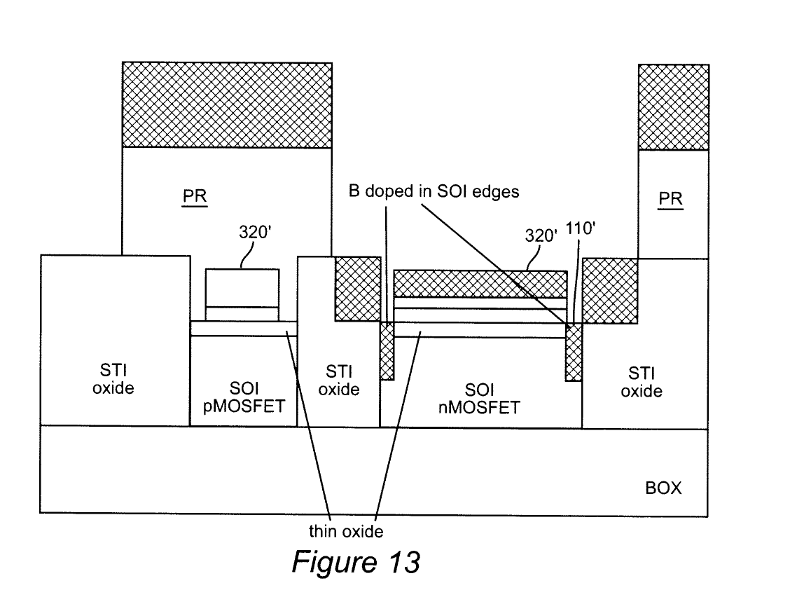

At this point, the PMOS channel structure is masked with a thick photoresist PR block-out mask as shown in FIG. 11. The thickness (e.g. preferably 200 Å-500 Å) of the PR layer is non-critical and preferably determined based on the energy of the boron implant which is, in turn, determined by the desired depth, preferably in the range of 10-50 nm, of the boron implant through thin oxide region 110′ at the bottom of gaps 330, as shown in FIG. 12. The width of the STI structures provides substantial registration tolerance for the patterning of the photoresist, as shown in FIG. 11. Then, as illustrated in FIG. 12, a boron implant is preformed on the structure of FIG. 11. It is preferable, in accordance with the principles of the invention that this implantation process be performed perpendicular to the substrate and in parallel with the gaps formed as discussed above rather than at an angle as discussed above in connection with FIG. 1A. The thickness of the photoresist PR prevents boron from reaching the PMOS channel while the nitride 320′ confines implantation of boron into NMOS channel 120b essentially to the corners thereof through gaps 330 and blocks implantation into the remainder of the channel. The resulting boron distribution pattern is illustrated by cross-hatching in FIG. 13. The photoresist can then be removed and the process of FIGS. 10-12 repeated for the PMOS channel, preferably using phosphorus and/or arsenic for the implanted species. It should be noted that only minimal, if any, heat treatment or annealing is required and the implants at the channel corners are confined substantially by the thickness developed in the deposited polysilicon layer discussed above (e.g. preferably 10-30 nm). It should be noted that this distance becomes less critical with increasing transistor channel width as NWE diminishes therewith and widths of impurity/dopant material distribution in excess of 50 nm are probably unnecessary, especially in SRAM applications. Conversely, as transistors are scaled to smaller sizes, especially in SRAM applications, NWE becomes more pronounced and an increased width of the implants may be desirable as narrow channel transistors are scaled to smaller minimum feature sizes and ground rules. Thus, in view of the increased accuracy and repeatability of deposition of materials such as polysilicon 310, the invention provides for engendering reverse NWE for both current and foreseeable ground rules as narrow channel transistors are scaled to smaller sizes.

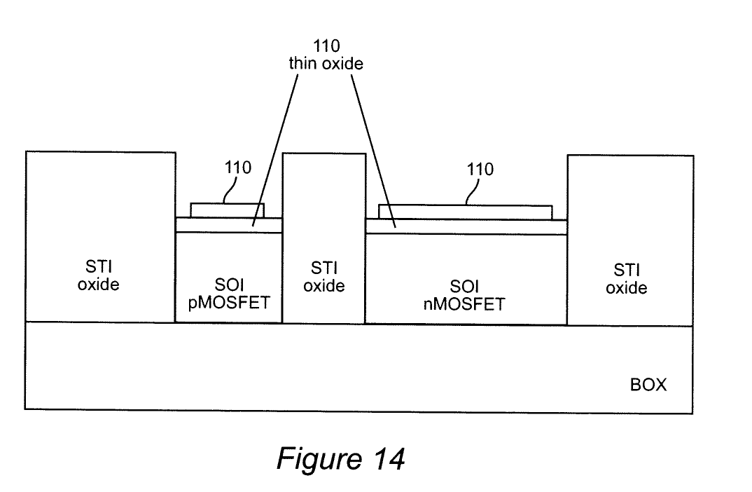

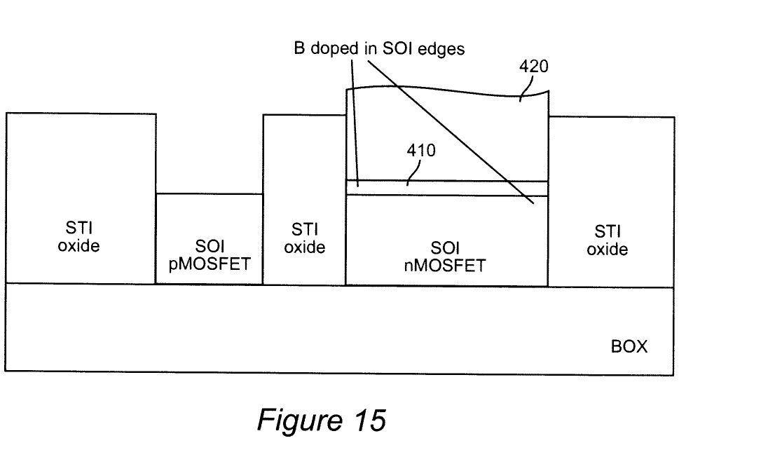

The remaining nitride deposits may then be etched selectively to the poly-Si 210 as shown in FIG. 14 and the poly-Si 210 etched away selectively to the remaining thin oxide 110 which can then, in turn, removed selectively to the underlying SOI. It should be noted that it is considered preferable to remove the remaining thin oxide in the manner of a sacrificial oxide because of the impurity/dopant distribution in the extremities thereof and to replace it with a high-quality gate oxide 410 and continue with formation of the gate structure 420, formation of the source and drain (in front and back of the plane of the page), silicidation, if desired, and other processes as may be desired for completion of the transistors (all of which are schematically represented by gate oxide 410 and gate electrode 420 in FIG. 15) using any known or foreseeable processes; all of which are compatible with the invention and the basic principles and techniques thereof as described above.

In view of the foregoing it is seen that the invention provides a structure and method for engendering reverse NWE in narrow channel transistors while avoiding undesired impurity/dopant distribution in complementary pairs of transistors formed within 100 nm or less of each other. The invention also provides for greatly improved accuracy and repeatability of impurity/dopant distribution which it applicable to current and foreseeable transistor designs and ground rules.

While the invention has been described in terms of a single preferred embodiment, those skilled in the art will recognize that the invention can be practiced with modification within the spirit and scope of the appended claims.

Having thus described my invention, what I claim as new and desire to secure by Letters Patent is as follows:

1. A field effect transistor comprising
a channel having a width sufficiently narrow to exhibit narrow width effects,
an implanted region at corners of said channel wherein impurities or dopant materials are confined to a width not exceeding 50 nm.

2. A field effect transistor as recited in claim 1 further comprising
a shallow trench isolation (STI) structure adjacent said channel, wherein a surface of said shallow trench isolation structure extends above a surface of said channel.

3. An integrated circuit comprising
at least one pair of field effect transistors of complementary conductivity types, wherein at least one field effect transistor of said pair of field effect transistors comprises
a channel having a width sufficiently narrow to exhibit narrow width effects,
an implanted region at corners of said channel wherein impurities or dopant materials are confined to a width not exceeding 50 nm.

4. An integrated circuit as recited in claim 3, wherein said impurities or dopant materials in said implanted region of said at least one transistor of said pair of field effect transistors are not present in another field effect transistor of said pair of field effect transistors.

5. An integrated circuit as recited in claim 3, further comprising
a shallow trench isolation (STI) structure adjacent said channel, wherein a surface of said shallow trench isolation structure extends above a surface of said channel.

6. A method of manufacture of a field effect transistor including steps of
developing raised STI structures on a substrate between regions of semiconductor material on a substrate,
depositing a layer of material selectively etchable to said STI structure over said STI structure and said regions of semiconductor materials,
developing a deposit of material over said layer of material between said STI structures which is selectively etchable to said layer of material,
removing exposed portions of said layer of material to form gaps at edges of said regions of semiconductor material,
masking selected regions of said semiconductor material,
implanting impurities or dopant materials through said gaps into said regions of semiconductor materials, and completing said field effect transistor.

7. The method as recited in claim 6, wherein said layer of material is polysilicon and said deposit of material is nitride.

8. The method as recited in claim 7, further comprising a step of
providing an etch stop material layer selectively etchable to said polysilicon and said nitride between said shallow trench isolation structures and over said regions of semiconductor material and wherein said step of depositing said layer of material deposits said layer of material on said etch stop material.

9. The method as recited in claim 8, wherein said etch stop material is oxide.

10. The method as recited in claim 9, wherein said step of implanting is performed through said etch stop material.

11. The method as recited in claim 6, further comprising a step of
providing an etch stop material layer selectively etchable to said layer of material and said deposit of material between said shallow trench isolation structures and over said regions of semiconductor material and wherein said step of depositing said layer of material deposits said layer of material on said etch stop material.

12. The method as recited in claim 11, wherein said step of implanting is performed through said etch stop material.
